(19) United States
(12) Patent Application Publication
(10) Pub. No.: US 2026/0351924 A1
(43) Pub. Date: Nov. 5, 2026

(54) LIGHT-EMITTING DEVICE

(71) Applicant: NICHIA CORPORATION, Anan-shi, Tokushima (JP)

(72) Inventors: Kazuma KOZURU, Anan-shi, Tokushima (JP); Shota MURAKAMI, Anan-shi, Tokushima (JP)

(21) Appl. No.: 19/488,529

(22) PCT Filed: Mar. 28, 2024
(86) PCT No.: PCT/JP2024/012786

§ 371 Date: Nov. 26, 2025

(30) Foreign Application Priority Data
May 31, 2023 (JP) 2023-089808
Oct. 24, 2023 (JP) 2023-182465

(51) Int. Cl. H01S 5/02315; H01S 5/02255; H01S 5/40

(52) U.S. Cl. CPC H01S 5/02315; H01S 5/02255; H01S 5/4025

(57) ABSTRACT

A light-emitting device includes a base using graphite as a primary material, a submount on a first upper face of the base, a first light emitting element on the submount and emitting light in a first direction, a reflecting member at a position distant from the first light emitting element in the first direction, and a frame defining a through hole, and having a second upper face, a lower face bonded to the base, and one or plurality of wiring layers disposed on the second upper face at a position distant from the first light emitting element in the opposite direction to the first direction. The first upper face has a first region covering the through hole in a top view and a second region disposed on the second upper face and extending from the first region to the area directly under the one or plurality of wiring layers.

### CROSS-REFERENCE TO RELATED APPLICATIONS

This application is a U.S. national stage application of International Application No. PCT/JP2024/012786, filed on Mar. 28, 2024. This application also claims priority to Japanese Patent Application No. 2023-089808, filed on Mar. 31, 2023, and Japanese Patent Application No. 2023-182465, filed on Oct. 24, 2023.

### TECHNICAL FIELD

The present invention relates to a light-emitting device.

### BACKGROUND ART

Japanese Patent Application Publication No. 2015-32706 discloses a semiconductor device which includes a semiconductor chip disposed on a submount formed of sheet shaped graphite. Graphite is an element having anisotropic thermal conductivity in which the thermal conductivity in one direction is higher than the thermal conductivity in another direction.

### SUMMARY

Disclosed here is a light emitting device which comprises a base for mounting a light emitting element, the base including graphite.

A light emitting device disclosed by an embodiment includes: a base using graphite as a primary material and having a first upper face; a submount disposed on the first upper face of the base; a first light emitting element disposed on the submount and emitting light in a first direction; a reflecting member disposed on the first upper face of the base at a position distant from the first light emitting element in the first direction; and a frame defining a through hole that surrounds the first light emitting element and the reflecting member in a top view and having a second upper face, a lower face bonded to the base, and a one or plural wiring layers disposed on the second upper face at a position distant from the first light emitting element in the opposite direction to the first direction. The first upper face of the base has a first region that covers the through hole in a top view and a second region disposed on the second upper face and extending from the first region to the area directly under the one or plural wiring layers.

In at least one of the one or plural inventions disclosed by the embodiments, a light emitting device including a base for mounting a light emitting element with a good heat dissipation property can be achieved.

### BRIEF DESCRIPTION OF DRAWINGS

FIG. 1 is a perspective view of a light emitting device according to a first embodiment.

FIG. 2 is a perspective view of a light emitting device according to the first embodiment and a second embodiment in which the optical member is not shown.

FIG. 3 is a perspective view showing the constituent elements arranged in the internal space of a package in the light emitting device according to the first embodiment.

FIG. 4A is a top view showing the constituent elements arranged in the internal space of the package in the light emitting device according to the first embodiment.

FIG. 4B is an end face view taken along line IVB-IVB in FIG. 4A.

FIG. 5 is a cross-sectional view taken along line V-V in FIG. 2.

FIG. 6 is a perspective view of a base according to the first and second embodiments.

FIG. 7 is a cross-sectional view of a base according to the first embodiment.

FIG. 8A is a top view showing a first example of the state in which an adhesive is disposed on the base according to the first and second embodiments.

FIG. 8B is a top view showing a second example of the state in which an adhesive is disposed on the base according to the first and second embodiments.

FIG. 8C is a top view showing a third example of the state in which an adhesive is disposed on the base according to the first and second embodiments.

FIG. 9 is a perspective view of a first graphite member according to the first and second embodiments.

FIG. 10 is a perspective view of a second graphite member according to the first and second embodiments.

FIG. 11 is a top view of a frame according to the first and second embodiments.

FIG. 12A is a bottom view of a first example of a second bonding layer disposed on the lower face of a frame according to the first and second embodiments.

FIG. 12B is a bottom view of a second example of the second bonding layer disposed on the lower face of the frame according to the first and second embodiments.

FIG. 12C is a bottom view of a third example of the second bonding layer disposed on the lower face of the frame according to the first and second embodiments.

FIG. 13 is a perspective view of a light emitting device according to the second embodiment.

FIG. 14 is a top view showing the constituent elements arranged in the internal space of a package in the light emitting device according to the second embodiment.

FIG. 15 is a cross-sectional view taken along line XV-XV in FIG. 2.

FIG. 16 is a cross-sectional view of a base according to the second embodiment.

### DESCRIPTION OF EMBODIMENTS

In the present specification and the scope of claims, a polygon, such as a triangle, rectangle, or the like, includes a shape subjected to processing, such as cutting angles, chamfering, beveling, rounding, or the like. Moreover, the location of such processing is not limited to a corner (an end of a side) of a polygon. Rather, a shape subjected to processing in the intermediate portion of a side will similarly be referred to as a polygon. In other words, any polygon-based shape subjected to partial processing should be understood to be included in the interpretation of a “polygon” disclosed in the present specification and the scope of claims.

This similarly applies to any word describing a specific shape, such as a trapezoidal, circular, recessed, or projected shape, without being limited to a polygon. This also similarly applies to the sides defining such shapes. In other words, even if a corner or intermediate portion of a side is subjected to processing, the term “side” should be interpreted to include the processed portion. To distinguish a “polygon” or “side” that is intentionally not processed from a shape subjected to processing, the shape will be described by adding the phrase “exact,” such as “an exact rectangle.”

In the present specification or the scope of claims, terms, such as up/down (upward/downward), left/right, front/back, front/rear (forward/rearward), in front/in the back, and the like merely describe a relationship between relative positions, directions, or orientations. Such a relationship does not have to match the relationship in actual use.

In the drawings, directions such as the X direction, the Y direction, and the Z direction might occasionally be indicated by arrows. These arrowed directions are consistent among multiple drawings related to the same embodiment. The directions pointed by the X, Y, and Z arrows are positive directions, and the opposite directions to these are negative directions. For example, the direction indicated as X in front of the arrow is the X direction and positive direction.

In the present specification, the direction that is X direction and positive direction is referred to as the “positive X direction,” and the direction opposite thereto is referred to as the “negative X direction.” The “X direction” includes both the positive and negative directions. The same applies to the Y and Z directions.

In the present specification, when describing a certain subject identified as being “one or plural,” both an embodiment having a single subject and an embodiment having plural subjects are collectively described. Accordingly, a description which identifies the subject as “one or plural” supports any of the cases in which an embodiment includes one or plural subjects, at least one subject, and plural subjects.

In the present specification, a description regarding “one or each” subject collectively describes cases in which an embodiment having a single subject and the single subject is described, an embodiment having plural subjects and one of the plural subjects is described, and an embodiment having plural subjects and each of the plural subjects is described. Accordingly, a description regarding “one or each” subject supports any of embodiments in which at least one subject is included and the description applies to the one subject, plural subjects are included and the description applies to at least one of the plural subjects, plural subjects are included and the description applies to each of the plural subjects, and one or plural subject are included and the description applies to each of the one or plural subject.

In the present specification, terms such as “member” and “part/portion” are used to describe a constituent element, for example. The term “member” refers to a subject that is treated as a single physical unit. A subject treated as a single physical unit can be considered as a component in the manufacturing process. The term “part/portion” refers to a subject that does not have to be treated as a single physical unit. The term “part/portion” is used, for example, to capture one part of a member, capture multiple members collectively as one subject, or the like.

A distinction made between the “member” and the “part/portion” described above is not intended to consciously limit the scope of the right in the interpretation of the doctrine of equivalence. In other words, even if there is a constituent element in the scope of claims disclosed as a “member,” the applicant does not recognize it essential based solely on that to treat the constituent element as a single physical unit in order to apply the present invention.

In the present specification and the scope of claims, when there are multiple pieces of elements having the same designation and a distinction must be made, a word such as “first,” “second,” or the like might occasionally be added to the element designation. There might be an occasion where the element designation with the same distinguishing word in the scope of claims and the description do not refer to the same element. For this reason, even if there are constituent elements recited in the scope of claims having the same distinguishing words as in the present specification, it is possible that the subjects identified by them do not match between the present specification and the scope of claims.

For example, in the case in which there are elements that are distinguished by the words, “first,” “second,” and “third,” in the present specification, and only the “first” and “third” elements are recited in a certain claim, they might be distinguished by the words, “first” and “second,” in the claim for readability. In such a case, the elements accompanied by the words, “first” and “second,” in the claim would refer to the subjects accompanied by the words, “first” and “third” in the description. This rule applies to not only constituent elements, but also other subjects in a reasonable and flexible manner.

Certain embodiments of the present invention will be explained below. Specific forms for implementing the present invention will be described with reference to the accompanying drawings. Forms for implementing the present invention are not limited to these specific forms. In other words, these embodiments illustrated are not the only forms for achieving the present invention. The sizes of and relative positions of the members illustrated might be exaggerated for clarity of explanation.

### First Embodiment

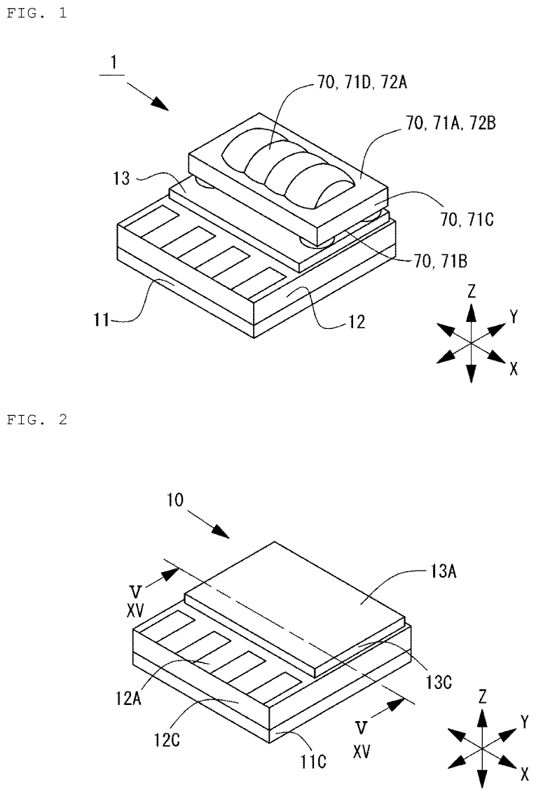

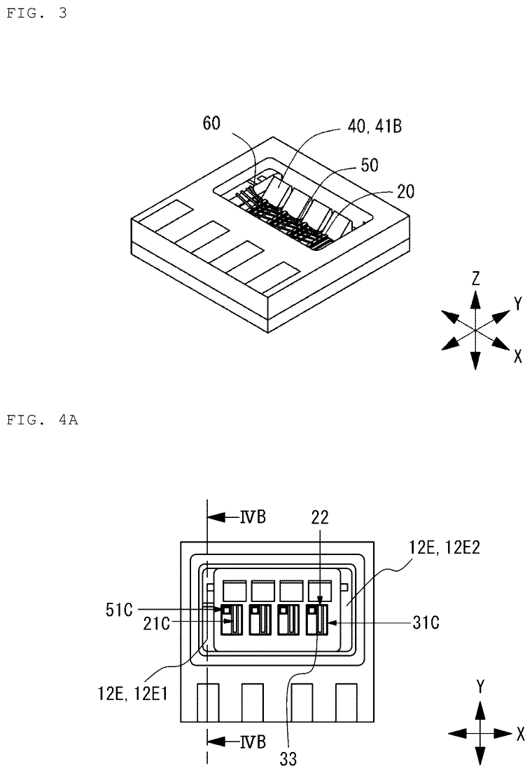

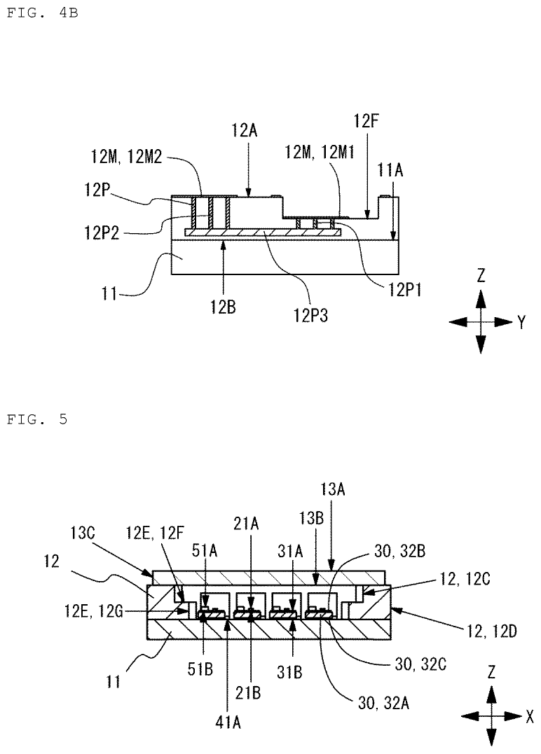

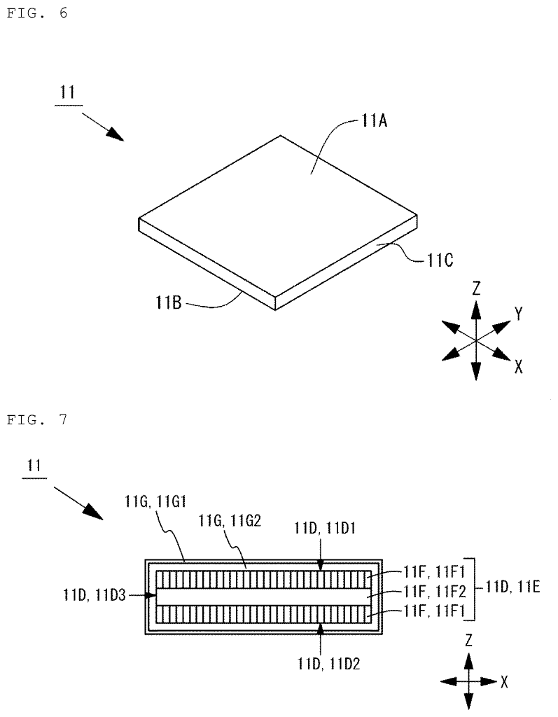

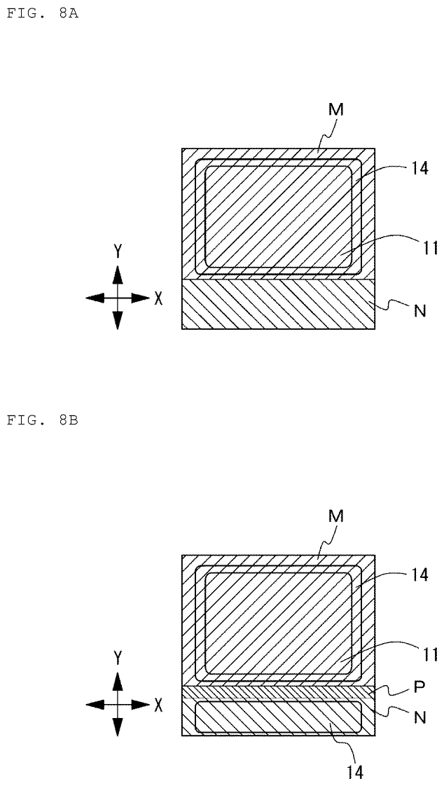

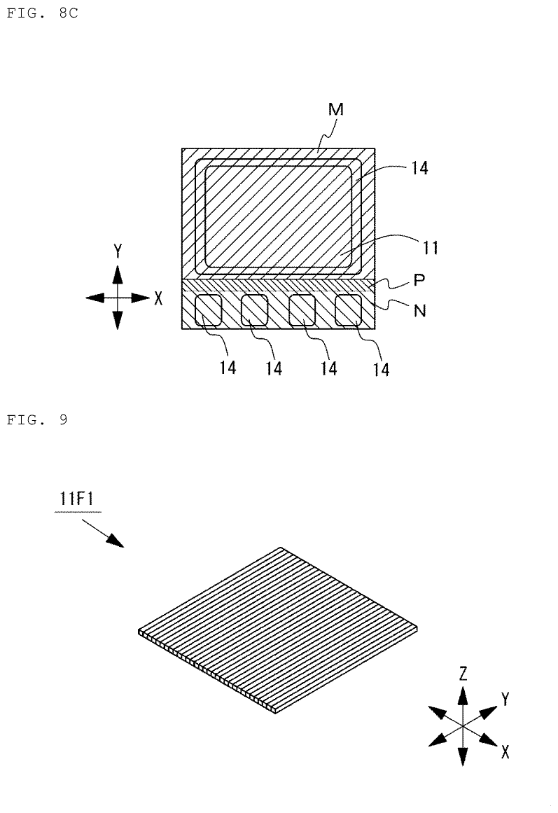

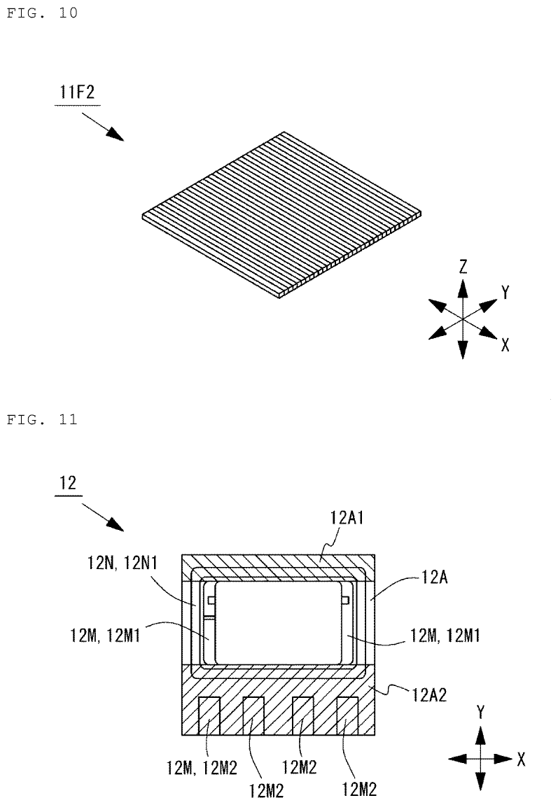

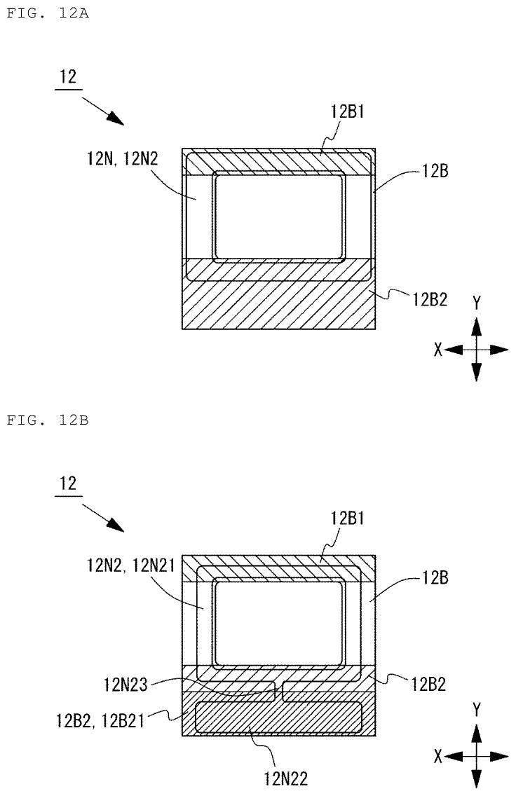

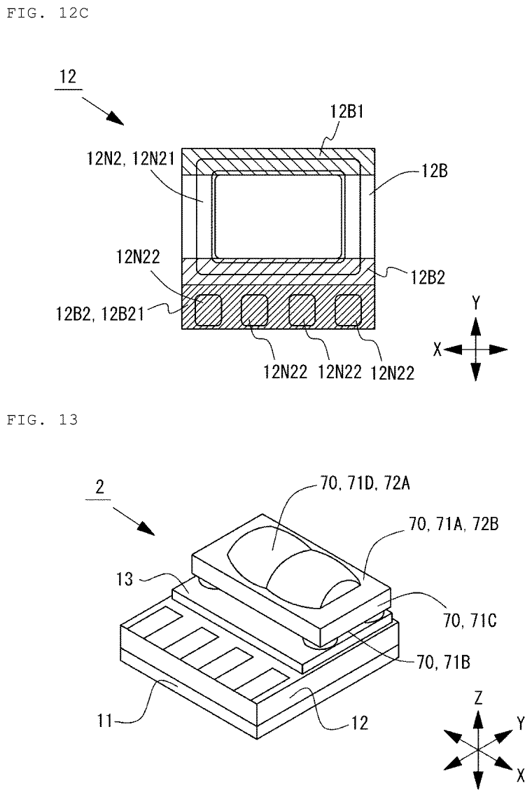

A light emitting device 1 according to a first embodiment will be explained. FIG. 1 to FIG. 12C are drawings explaining an exemplary form of the light emitting device 1. FIG. 1 is a perspective view of the light emitting device 1. FIG. 2 is a perspective view of the light emitting device 1 in the state in which the optical member 70 is now shown. FIG. 3 is a perspective view of the constituent elements arranged in the internal space of the package 10 in the light emitting device 1. FIG. 4A is a top view in the state shown in FIG. 3. FIG. 4B is an end face view taken along line IVB-IVB in FIG. 4A. In FIG. 4B, the first portions 12p1, the second portions 12p2, and the third portion 12P3 of the via wires 12P are indicated with hatching lines. FIG. 5 is a cross-sectional view taken along line V-V in FIG. 2. FIG. 6 is a perspective view of a base 11. FIG. 7 is a cross-sectional view of the base 11 in the light emitting device 1. FIG. 8A is a top view showing a first example of the state in which an adhesive 14 is disposed on the base 11. FIG. 8B is a top view showing a second example of the state in which an adhesive 14 is disposed on the base 11. FIG. 8C is a top view showing a third example of the state in which an adhesive 14 is disposed on the base 11. In FIG. 8A to FIG. 8C, the first region M and the second region N of the base 11 are indicated with hatching lines. In FIGS. 8B and 8C, the third region P of the base 11 is further indicated by hatching lines. FIG. 9 is a perspective view of a first graphite member 11F1. FIG. 10 is a perspective view of a second graphite member 11F2. FIG. 11 is a top view of a frame 12. In FIG. 11, the narrow-width portion 12A1 and the wide-width portion 12A2 in the upper face 12A of the frame 12 are indicated with hatching lines. FIG. 12A is a bottom view showing a first example of a second bonding layer 12N2 disposed on the lower face 12B of the frame 12. FIG. 12B is a bottom view showing a second example of the second bonding layer 12N2 disposed on the lower face 12B of the frame 12. FIG. 12C is a bottom view showing a third example of the second bonding layer 12N2 disposed on the lower face 12B of the frame 12. In FIG. 12A to FIG. 12C, the narrow-width portion 12B1 and the wide-width portion 12B2 of the bottom face 12B of the frame 12 are indicated with hatching lines. In FIG. 12B and FIG. 12C, the expanded portion 12B21 in the wide-width portion 12B2 is further indicated with hatching lines. In the package 10, the example of frame 12 shown in FIG. 12A corresponds to the example of base 11 shown in FIG. 8A, the example of frame 12 shown in FIG. 12B corresponds to the example of base 11 shown in FIG. 8B, and the example of frame 12 shown in FIG. 12C corresponds to the example of base 11 shown in FIG. 8C.

A light emitting device 1 includes a plurality of constituent elements. The constituent elements include a package 10, one or plural light emitting elements 20, one or plural submounts 30, one or plural reflecting members 40, one or plural protective elements 50, plural wires 60, and an optical member 70.

A light emitting device 1 may include additional constituent elements. For example, a light emitting device 1 may include additional light emitting elements besides the one or plural light emitting elements 20. A light emitting device 1 does not have to include all of the constituent elements listed above.

Each constituent element will be explained.

### Package 10

A package 10 includes a base 11 and a frame 12. The package 10 further includes a lid 13. In the package 10, an internal space is defined in which other constituent elements are arranged. The internal space is a closed space enclosed by the base 11, the frame 12, and the lid 13. The internal space can be a vacuum or airtight sealed space.

The base 11 has an upper face 11A. The base 11 has a lower face 11B and one or plural lateral faces 11C. The shape of the base 11 is a flat sheet or cuboid. The shape of the upper face 11A is a quadrangle. The shape of the upper face 11A is a quadrangle having long sides and short sides.

The length of the base 11 in the X direction is, for example, 3 mm to 15 mm. The length of the base 11 in the Y direction is, for example, 5 mm to 10 mm. The thickness of the base 11 in the Z direction is, for example, 0.5 mm to 5 mm.

The primary material for the base 11 is graphite. The base 11 has a main part 11D formed primarily of graphite, and one or plural metal layers 11G disposed on the main part 11D. The one or plural metal layers 11G can include a first metal layer 11G1 and a second metal layer 11G2.

Here, a primary material refers to a material occupying the largest portion in mass or volume of a subject formed body. In the case in which the subject formed body is made of a single material, the material is the primary material. In other words, a given material being a primary material of a subject includes the case in which the material constitutes 100% of the subject.

The main part 11D has an upper face 11D1. The main part 11D further has a lower face 11D2 and one or plural lateral faces 11D3. The shape of the main part 11D is a flat sheet or cuboid. The shape of the upper face 11D1 is a quadrangle. The shape of the upper face 11D1 is a quadrangle having long sides and short sides.

The main part 11D can be formed of a graphite stack 11E in which plural graphite members 11F are stacked. The direction in which plural graphite members 11F are stacked in the graphite stack 11E is the direction that is perpendicular to the upper face 11A of the base 11 and the upper face 11D1 of the main part 11D.

A graphite member 11F has anisotropic thermal conductivity. In an XYZ space, the thermal conductivity in the two-dimensional planar direction is higher than the thermal conductivity in the direction perpendicular to the two-dimensional plane. For example, when the X direction and the Y direction is the high thermal conduction directions, the Z direction is the low thermal conduction direction. The terms “high” and “low” in high conduction directions and low thermal conduction direction are used to relatively express the thermal conductivity of one being higher or lower than that of the other.

A graphite member 11F can be formed by stacking plural graphene sheets. A graphene sheet is sheet-shaped graphene in which hexagonal rings of carbon are two-dimensionally covalently bonded. In such a graphene sheet stack, the stacking direction becomes the low thermal conduction direction, and the direction perpendicular to the stacking direction becomes the high thermal conduction direction. Specifically, the thermal conductivity in the stacking direction is about 5 [W/mK] to 10 [W/mK], and the thermal conductivity in the direction perpendicular to the stacking direction is about 1500 [W/mk] to 1700 [W/mk]. Using graphite as a primary material can achieve a base 11 that excels in heat dissipation.

A graphite stack 11E is formed by stacking plural graphite members 11F such that the direction in which the graphite members 11F are stacked becomes the high thermal conduction direction. Accordingly, the stacking direction of the graphite members 11F is perpendicular to the stacking direction of graphene sheets in each graphite member 11F. Hereinafter, the stacking direction of the graphite members 11F will be referred to as the first stacking direction, and the stacking direction of graphene sheets in each graphite member 11F will be referred to as the second stacking direction.

The graphite stack 11E is formed by stacking graphite members 11F such that the high thermal conduction directions are alternately different in planes perpendicular to the first stacking direction. For example, on a graphite member 11F whose high thermal conduction directions are the X direction and the Z direction, another graphite member 11F whose high thermal conduction directions are the Y direction and the Z direction is stacked. Stacking graphite members 11F to alternate the high thermal conduction directions in this manner can create a graphite stack 11E having high thermal conduction directions in all directions artificially.

Here, a graphite member 11F having higher thermal conductivity in the first direction than in the second direction that is perpendicular to the first direction will be referred to as a first graphite member 11F1, and a graphite member 11F having higher thermal conductivity in the second direction than in the first direction will be referred to as a second graphite member 11F2. In the example of graphite stack 11E shown in the drawings, the first direction is the Y direction and the second direction is the X direction.

A graphite member 11F having the first direction as the high thermal conduction direction and the second direction as the low conductivity direction in a plane that is perpendicular to the first stacking direction can be considered as a first graphite member 11F1, and a graphite member 11F having the second direction as the high thermal conduction direction and the first direction as the low thermal conduction direction in a plane that is perpendicular to the first stacking direction can be considered as a second graphite member 11F2. A plane perpendicular to the first stacking direction is parallel to the upper face 11A of the base 11.

A graphite stack 11E is formed by stacking first graphite members 11F1 and second graphite members 11F2. The first graphite members 11F1 and the second graphite members 11F2 do not necessarily have to be staked alternately. For example, a second graphite member 11F2 may be stacked on two consecutively stacked first graphite members 11F1.

A graphite stack 11E includes at least one first graphite member 11F1 and one second graphite member 11F2. The graphite stack 11E is preferably constructed such that the uppermost and lowermost layers are both first graphite members 11F1 or both second graphite members 11F2. When both the uppermost and lowermost layers are either first graphite members 11F1 or second graphite members 11F2, the strain on the upper face side and the strain on the lower face side would not be unbalanced. This can enhance the shape stability of the graphite stack 11E.

The meta layer 11G or each metal layer 11G is disposed on the upper face 11D1. The meta layer 11G or each metal layer 11G can be disposed on the lower face 11D2 or the one or plural lateral faces 11D3. The meta layer 11G or each metal layer 11G can be disposed on the upper face 11D1, the lower face 11D2, and the one or plural lateral faces 11D3. The meta layer 11G or each metal layer 11G can be disposed to cover all of the faces of the main part 11D.

A first metal layer 11G1 is disposed on the upper face 11D1 of the main part 11D. The first metal layer 11G1 constitutes the upper face 11A of the base 11. A second metal layer 11G2 is disposed on the upper face 11D1 of the main part 11D. The second metal layer 11G2 is disposed between the upper face 11D1 and the first metal layer 11G1.

Accordingly, the first metal layer 11G1 is disposed above the second metal layer 11G2.

The second metal layer 11G2 having a thickness in a range of 0.1 [symbol] to 100 [symbol] is disposed on the main part 11D. This can reduce crack formation on the upper face 11A that might occur in response to a crack formed in the main part 11D. The second metal layer 11G2 is disposed to cover all faces of the main part 11D.

The first metal layer 11G1 having a thickness in a range of 0.1 [symbol] to 5 [symbol] is disposed on the main part 11D.

The second metal layer 11G2 is larger than the first metal layer 11G1 in thickness. Because the upper face 11A of the base 11 can be bonded to another constituent element, the material for the first metal layer 11G1 can be selected from the bonding standpoint while allowing the second metal layer 11G2 to reduce crack formation in the upper face 11A. At this time, the first metal layer 11G1 does not have to have a larger thickness than the second metal layer 11G2.

The first metal layer 11G1 is disposed to cover all faces of the second metal layer 11G2. Covering all faces of the second metal layer 11G2 can lessen the deterioration of the second metal layer 11G2 by oxidation or the like.

The first metal layer 11G1 can be a metal layer containing Ni or Au. For example, the first metal layer 11G1 can be formed by Ni/Au plating. The second metal layer 11G2 can be a metal layer containing Cu. The second metal layer 11G2 can be formed by using Cu as a primary material. For example, the second metal layer 11G2 can be formed with Cu plating.

A frame 12 has an upper face 12A and a lower face 12B. The frame 12 has one or plural inner lateral faces 12C and one or plural outer lateral faces 12D. The one or plural inner lateral faces 12C meet the upper face 12A. In a top view, a frame is formed by the upper face 12A. In a bottom view, a frame is formed by the lower face 12B. The frame 12 defines a through hole in the up/down direction inward of the frame. For each of the upper face 12A and the lower face 12B, the frames defined by the inner edges and the outer edges can be referred to as the inner frame and the outer frame, respectively.

The outer edge shape (outer frame shape) of the frame 12 is quadrangular. The outer edge shape is a quadrangle having long sides and short sides. The outer frame shape is quadrangular. The outer frame shape is a quadrangle having long sides and short sides. The inner edge shape (inner frame shape) of the frame 12 is quadrangular.

The inner frame shape is a quadrangle having long sides and short sides.

In a top view, the long sides of the outer frame of the frame 12 are parallel to the long sides of the inner frame. In a top view, the long sides of the outer frame of the frame 12 may be perpendicular to the long sides of the inner frame. Hereinafter, when “short sides” and “long sides” are mentioned with respect to the frame 12, they refer to the short sides and the long sides of the inner frame of the frame 12 unless otherwise specifically noted. The frame 12 illustrated is an example in which the direction parallel to the long sides of the inner frame is the X direction, and the direction parallel to the short sides of the inner frame is the Y direction in a top view.

In the frame 12, the center of the outer frame does not coincide with the center of the inner frame in a top view. Here, in a top view, the direction parallel to one of the four sides of the quadrangular frame 12 is designated as the third direction, and the direction perpendicular to the side is designated as the fourth direction. The coordinates of the center of the t outer frame coincides with the coordinates of the center of the inner frame of the frame 12 in the third direction, but not in the fourth direction. The frame 12 illustrated is an example in which the third direction is the X direction and the fourth direction is the Y direction.

The upper face 12A has regions which have different widths from the inner frame to the outer frame of the frame 12 between two opposing sides. The upper face 12A has regions having the same width from the inner frame to the outer frame of the frame 12 between the other two opposing sides. In the frame 12 illustrated, the widths of the upper face 12A from the inner frame to the outer frame differ along the two opposing long sides. The widths of the upper face 12A from the inner frame and the outer frame are the same along the two opposing short sides. The width from the inner frame to the outer frame in other words is the distance from an inner lateral face 12C to the corresponding outer lateral face 12D.

In the upper face 12A, of the two regions having different widths from the inner frame to the outer frame of the frame 12 between two opposing sides, the region having a narrower width will be referred to as the narrow-width portion 12A1, and the region having a wider width the wide-width portion 12A2. Of the four sides that define a quadrangular frame, a side related to the narrow-width portion 12A1 will be referred to as a first side, and a side related to the wide-width portion 12A2 will be referred to as a second side. Accordingly, there are two first sides in the narrow-width portion 12A1 and two second sides in the wide-width portion 12A2. In other words, there are first and second sides on the inner frame where the upper face 12A meets the inner lateral faces 12C, and first and second sides on the outer frame where the upper face 12A meets the outer lateral faces 12D.

In the frame 12 illustrated, in a top view, the region between the inner lateral face 12C and the outer lateral face 12D along one of the two opposing long sides is the narrow-width portion 12A1, and the region between the inner lateral face 12C and the outer lateral face 12D along the other long side is the wide-width portion 12A2.

The frame 12 further has one or plural stepped portions 12E. A stepped portion 12e has an upper face 12f and a lateral face 12G meeting the upper face 12F and extending from the upper face 12F downwards. Here, a stepped portion 12E has one upper face 12F and one lateral face 12G only. Accordingly, stepped portions 12E have no inner lateral faces 12C. The one or plural stepped portions 12E is/are provided inward of the inner frame of the frame 12 in a top view. When viewed as a frame 12, the lateral face 12G is an inner lateral face, not an outer lateral face.

The one or plural stepped portions 12E can include a first stepped portion 12E1 and a second stepped portion 12E2. The first stepped portion 12E1 and the second stepped portion 12E2 are located such that their lateral faces 12G oppose one another. The first stepped portion 12E1 and the second stepped portion 12E2 are provided along the inner lateral faces 12C along the short sides. The direction in which the lateral face 12G of the first stepped portion 12E1 faces the lateral face 12G of the second stepped portion 12E2 is the same as the direction in which the inner lateral faces 12C along the short sides face one another.

The lateral face 12G of a stepped portion 12E meets the lower face 12B of the frame 12. The short sides of the inner frame formed in the lower face 12B are included in the lateral faces 12G, and the long sides of the inner frame formed in the lower face 12B are included in the inner lateral faces 12C.

In the frame 12, the center position of the outer frame does not coincide with the center position of the inner frame in a bottom view. The lower face 12B has regions which have different widths from the inner frame to the outer frame of the frame 12 between two opposing sides. The lower face 12B has regions having the same width from the inner frame to the outer frame of the frame 12 between the other two opposing sides. In the frame 12 illustrated, the widths from the inner frame to the outer frame of the lower face 12B differ along two opposing long sides. The widths from the inner frame to the outer frame of the lower face 12B are the same along the two opposing short sides. The width from an inner frame to an outer frame in other words is the distance from the inner lateral face 12C to the corresponding outer lateral face 12D.

In the lower face 12B, of the two regions having different widths from the inner frame to the outer frame of the frame 12 between two opposing sides, the region having a narrower width will be referred to as the narrow-width portion 12B1, and the region having a wider width the wide-width portion 12B2. Of the four sides that define a quadrangular frame, a side related to the narrow-width portion 12B1 will be referred to as a first side, and a side related to the wide-width portion 12B2 will be referred to as a second side. Accordingly, there are two first sides in the narrow-width portion 12B1 and two second sides in the wide-width portion 12B2. In other words, there are first and second sides on the inner frame where the lower face 12B meets the inner lateral faces 12C or the lateral faces 12G, and first and second sides on the outer frame where the lower face 12B meets the outer lateral faces 12D.

In the frame 12 illustrated, in a bottom view, the region between the inner lateral face 12C and the outer lateral face 12D along one of the two opposing long sides is the narrow-width portion 12B1 and the region between the inner lateral face 12C and the outer lateral face 12D along the other long side is the wide-width portion 12B2.

In a top view and a inner side view of the inner frame, the first sides in the upper face 12A are located on the same side as the first sides in the lower face 12B. In a top view and a inner side view of the inner frame, the second sides in the upper face 12A are located on the same side as the second sides in the lower face 12B.

The frame 12 further has plural wiring layers 12M. The wiring layers 12M include one or plural first wiring layers 12M1 disposed inward of the inner frame of the frame 12 in a top view. The wiring layers 12M further include one or plural second wiring layers 12M2 disposed outward from the inner frame of the frame 12.

The first wiring layer 12M1 or each first wiring layer 12M1 is disposed on the upper face 12F of a stepped portion 12E. The second wiring layer 12M2 or each second wiring layer 12M2 is disposed on the upper face 12A. The second wiring layer 12M2 or each second wiring layer 12M2 is disposed on the wide-width portion 12A2. The second wiring layer 12M2 or each second wiring layer 12M2 is enclosed by the wide-width portion 12A2 in a top view.

The one or plural first wiring layers 12M1 are electrically connected to the one or plural wiring layers 12M2. The first wiring layer 12M1 or each first wiring layer 12M1 is electrically connected to the second wiring layer 12M2 via a via wire 12P. The second wiring layer 12M2 or each second wiring layer 12M2 is electrically connected to the first wiring layer 12M1 via a via wire 12P.

The frame 12 includes one or plural via wires 12P. The one or plural via wires 12P are disposed inside the frame 12. The via wire 12P or each via wire 12P is connected to the first wiring layer 12M1. The via wire 12P or each via wire 12P is connected to the second wiring layer 12M2. The first wiring layer 12M1 and the second wiring layer 12M2 are electrically connected as the via wires 12P are connected to the first wiring layer 12M1 and the second wiring layer 12M2.

The via wire 12P or each via wire 12P has a first

### Portion 12p1 Connected to the First Wiring Layer 12m1, a

second portion 12P2 connected to the second wiring layer 12M2, and a third portion 12P3 extending in the direction parallel to the upper face 12A. The first portion 12P1 extends up and down. The second portion 12P2 extends up and down. The third portion 12P3 connects the first portion 12P1 and the second portion 12P2. In the light emitting device 1 illustrated, the third portion 12P3 of the via wires 12P extends in the Y direction.

In the via wire 12P or each via wire 12P, the third portion 12P3 is disposed at the closest position to the lower face 12B of the frame 12. The distance from the lower face 12B of the frame 12 to the third portion 12P3 of the via wire 12P is greater than 0 and 1000 μm at most. The distance is preferably set to 500 μm at most. Setting the distance to 500 μm at most can facilitate the heat transfer from the third portion 12P3 to the lower face 12B.

In the via wires 12P or each via wire 12P, the up/down distance from the lower face 12B of the frame 12 to the third portion 12P3 of the via wire 12P is smaller than the up/down distance from the first wiring layer 12M1 connected to the first portion 12P1 this via wire 12P to the third portion 12P3. Disposing the third portion 12P3 which is located closest to the lower face 12B of the frame 12 in this manner can facilitate the heat transfer from the via wires 12P to the lower face 12B.

In the via wire 12P or each via wire 12P, the up/down distance from the lower face 12B of the frame 12 to the third portion 12P3 is smaller than the up/down distance from the first wiring layer 12M1 connected to the first portion 12P1 of this via wire 12P to the third portion 12P3 by at least 50 μm.

The one or plural first wiring layers 12M1 are positioned lower than the one or plural second wiring layers 12M2. The up/down distance from the lower face 12B of the frame 12 to the third portion 12P3 of the via wires 12P is smaller than the up/down distance from the second wiring layers 12M2 to the third portion 12P3.

The thermal conductivity of the via wires 12P is 100 [W/mK] to 500 [W/mK]. The thermal conductivity of the via wires 12P can be 150 [W/mK] to 500 [W/mK]. The thermal conductivity of the via wires 12P is lower than the thermal conductivity of the graphite members 11F in the high thermal conduction direction and higher than the thermal conductivity of the graphite members 11F in the low thermal conduction direction.

The frame 12 further has one or plural bonding layers 12N. The one or plural bonding layers 12N include a frame-shaped first bonding layer 12N1 near the inner frame of the upper face 12A in a top view. The bonding layers 12N include a frame-shaped second bonding layer 12N2 disposed near the inner frame of the lower face 12B in a bottom view. For example, the frame 12 does not have to have a first bonding layer 12N1.

As shown in FIG. 12A, the second bonding layer 12N2 can be formed only with a portion disposed near the inner frame of the lower face 12B. As shown in FIG. 12B, the second bonding layer 12N2 can be composed of a first portion 12N21 disposed near the inner frame of the lower face 12B, a second portion 12N22 disposed directly under the one or plural second wiring layers 12M2, and a third portion 12N23 disposed between the first portion 12N21 and the second portion 12N22. As shown in FIG. 12C, the second bonding layer 12N2 can have a first portion 12N21 disposed near the inner frame of the lower face 12B, and one or plural second portions 12N22 disposed directly under the one or plural second wiring layers 12M2 in which the first portion 12N21 and the second portion 12N22 are disposed apart from one another.

In the upper face 12A, the first bonding layer 12N1 is disposed apart from all of the wiring layers 12M. The distance from the outer frame or outer edge of the portion of the second bonding layer 12N2 located near the inner frame of the lower face 12B in the wide-width portion 12B2 to the second side on the outer frame of the lower face 12B is larger than the distance from the outer frame or outer edge of the second bonding layer 12N2 in the narrow-width portion 12B1 of the lower face 12B to the first side on the outer frame of the lower face 12B. Here, the difference between the former and latter distances will be referred to as a first difference.

Assuming that the difference between the width of the portion of the second bonding layer 12N2 located near the inner frame of the lower face 12B in the wide-width portion 12B2 and the width of the second bonding layer 12N2 located in the narrow-width portion 12B1 is a second difference, the first difference is larger than the second difference. In the frame 12 illustrated, the width of the portion of the second bonding layer 12N2 located near the inner frame of the lower face 12B in the wide-width portion 12B2 is equal to the width of the second bonding layer 12N2 located in the narrow-width portion 12B1. Here, “being equal to” includes a tolerance of up to 50 μm.

When the wide-width portion 12B2 is divided into two regions by the straight line that goes through the center of the width from the second side on the inner frame to the second side on the outer frame of the wide-width portion 12B2 and is parallel to the second side, the outer frame or outer edge of the portion of the second bonding layer 12N2 located near the inner frame of the lower face 12B in the wide-width portion 12B2 is located in the region, of the two regions, that includes the second side on the inner fame of the wide-width portion 12B2.

As shown in FIG. 12B and FIG. 12C, the second portion 12N22 of the second bonding layer 12N2 can be composed of one or plural regions. In the case in which the second portion 12N22 is composed of plural regions, the regions are located apart from one another. In a bottom view, the second portion 12N22 or each second portion 12N22 is quadrangular.

The second bonding layer 12N2 having a second portion 12N22 allows an adhesive to be disposed directly under the one or plural second wiring layers 12M2, thereby filling the gap between the upper face 11A of the base 11 and the lower face 12B of the frame 12 in the regions in which the second wiring layers 12M2 are provided. Because wires might be bonded to the second wiring layers 12M2 by using bonding equipment, filling the gap can reduce the risks of the frame 12 being damaged by the wire bonding process.

There is a space of 200 μm or larger between the first portion 12N21 and the second portion 12N22 of the second bonding layer 12N2 in the Y direction. Providing a 200 μm or larger space can keep the adhesive 14 applied for bonding the second portion 12N22 from flowing onto the first portion 12N21.

In a top view, the percentage of the regions in which the one or plural second wiring layers 12M2 overlap the second portions 12N22 in the regions in which one or plural second wiring layers 12M2 are disposed can be 40% to 100%. The percentage is preferably 50% or higher. The higher the percentage, the lower the risk of the damage described above results.

As shown in FIG. 12B, the third portion 12N23 of the second bonding layer 12N2 is the portion that connects the first portion 12N21 and the second portion 12N22. Forming the second bonding layer 12N2 as a single connected region in this manner can facilitate the bonding process in the case in which the upper face 11A of the base 11 and the lower face 12B of the frame 12 are bonded by a method that uses an electric current such as electroplating.

As shown in FIG. 12B, the width of the third portion 12N23 in the X direction is smaller than the distance between the two ends of the first portion 12N21 in the X direction. The width of the third portion 12N23 in the X direction is smaller than the distance between the two ends of the second portion 12N22 in the X direction. Setting the width of the connecting portion to be relatively small in this manner can lessen the extension of the adhesive for bonding the second portion 12N22 to the first portion 12N21.

As shown in FIG. 12C, positioning the first portion 12N21 and the second portions 12N22 apart from one another can also lessen the extension of the adhesive for bonding the second portion 12N22 to the first portion 12N21.

In the upper face 12A, the distance from the first side on the outer frame to the second side on the inner frame is larger than the distance from the second side on the outer frame to the second side on the inner frame. In the upper face 12A, the distance from the first side on the inner frame to the second side on the inner frame is larger than the distance from the second side on the outer frame to the second side on the inner frame.

In the lower face 12B, the distance from the first side on the outer frame to the second side on the inner frame is larger than the distance from the second side on the outer frame to the second side on the inner frame. In the lower face 12B, the distance from the first side on the inner frame to the second side on the inner frame is larger than the distance from the second side on the outer frame to the second side on the inner frame.

A frame 12 can be formed by using a ceramic as a primary material, for example. Examples of ceramics for use as a primary material for the frame 12 include aluminum nitride, silicon nitride, aluminum oxide, silicon carbide, and the like.

A wiring layer 12M can be formed by using a metal material as a primary material, for example. Examples of metal materials for use as a primary material for the wiring layer 12M include simple metals, such as Cu, Ag, Ni, Au, Ti, Pt, Pd, Cr, W, and the like, or alloys containing these metals.

A bonding layer 12N can be formed by using a metal material as a primary material, for example. Examples of metal materials for use as a primary material for the bonding layer 12N include simple metals, such as Cu, Ag, Ni, Au, Sn, Ti, Pd, and the like, or alloys containing these metals.

The frame 12 is bonded to the base 11. The lower face 12B of the frame 12 is bonded to the base 11. The lower face 12B is bonded to the upper face 11A. The metal layer 11G constituting the upper face 11A of the base 11 can reduce crack formation and gas leakage at the bonded portion as compared to directly bonding the frame 12 to graphite. The frame 12 is bonded to the first metal layer 11G1 of the base 11. The second bonding layer 12N2 of the frame 12 is bonded to the base 11. The frame 12 is bonded to the base 11 via an adhesive 14.

The frame 12 being bonded to the base 11 allows the heat generated at the via wires 12P to transfer from the lower face 12b to the base 11, thereby facilitating heat dissipation. Because the direction in which the third portion 12P3 of the via wires 12P is elongated is aligned with the high thermal conduction direction of the graphite member 11F closest to the upper face 11A of the base 11, the heat can be readily dissipated in the direction in which the third portion 12P3 is elongated.

The up/down distance from the third portion 12P3 of the via wires 12P to the upper face 11A of the base 11is smaller than the up/down distance from the third portion 12P3 to the first wiring layer 12M1 connected to the first portion 12P1 of this via wires 12P. This facilitates the transfer of the heat generated at the via wires 12P to the base 11.

The adhesive 14 used to bond the base 11 to the frame 12 is disposed on the upper face 11A of the base 11 in a frame shape. Before bonding the base 11 and the frame 12, the adhesive 14 may be continuously disposed to form a frame shape, or disposed in pieces to collectively form a frame shape. For example, by arranging ball-shaped adhesive 14 along a frame shape, the adhesive 14 can form a frame shape in separate parts.

Before bonding the base 11 and the frame 12, the adhesive 14 is disposed on the upper face 11A of the base 11 in a frame shape so as to be contained in the frame formed by the second bonding layer 12N2 of the frame 12. In other words, the region in which the adhesive 14 is disposed can be enclosed by applying the shape of the region enclosed by the inner frame and the outer frame of the second bonding layer 12N2.

Because the frame 12 is bonded to the base 11 via the adhesive 14 disposed as described above, the adhesive 14 is disposed near the inner frame or near inner edges of the lower face 12B that defines the through hole. Disposing the adhesive 14 near the inner edges of the lower face 12B can make the size of the frame shape formed by the adhesive smaller than disposing the adhesive 14 near the outer edges of the lower face 12B, requiring a smaller amount of adhesive to bond the frame 12 to the base 11.

The adhesive 14 hardened by the bonding process has a continuous frame shape. This can sufficiently suppress the gas leakage from or penetration into the space sealed by the base 11 and the frame 12.

In the example shown in FIG. 8A, the adhesive 14 is not disposed directly under at least a portion of the second wiring layers 12M2. Reducing the bonding area of the adhesive 14 can reduce the heat transfer path between the base 11 and the frame 12, thereby achieving a package with a good heat dissipation property. Because the adhesive 14 hardens in a shape that is similar to the shape of the second bonding layer 12N2, the adhesive 14 can be disposed so as not to be located directly under the second wiring layer 12M2 or each second wiring layer 12M2.

In the examples shown in FIG. 8B and FIG. 8C, the adhesive 14 is disposed directly under at least a portion of the second wiring layers 12M2. This can reduce the risks of damaging the frame 12 attributed to a process that applies a load to the second wiring layers 12M2 such as a wire bonding process performed on the second wiring layers 12M2.

It is not essential for the adhesive 14 to be laid out to encompass the one or plural second wiring layers 12M2 in a top view, but the adhesive preferably overlaps 50% or more of the regions where the one or plural second wiring layers 12M2 are disposed. The adhesive 14 preferably overlaps 50% or more of the region where each second wiring layer 12M2 is disposed. The higher the percentage of the overlapped region, the lower the risks of damage result.

In a Top View, the Outer Edge Shape of the Upper face 11A of the base 11 is larger than the inner frame of the frame 12. In a top view, the outer edge shape of the upper face 11A is substantially the same as or larger than the outer edge shape (outer frame shape) of the frame 12. Here, F “substantially the same” includes the case in which the outer edge shape of the upper face 11A is slightly smaller than the outer edge shape of the frame 12. The base 11 having a large outline can achieve a package 10 with a good heat dissipation property.

The upper face 11A of the base 11 has a first region M that covers the through hole of the frame 12 and a second region N that extends from the first region M to the area directly under the second wiring layers 12M2 disposed on the upper face 12A of the frame 12 in a top view. Expanding the upper face 11A of the base 11 from near the through hole to directly under the second wiring layer 12M2 can increase the area of the upper face 11A of the base 11, thereby achieving a package 10 with a good heat dissipation property. The second region N of the upper face 11A has a region in which the adhesive 14 for bonding the base 11 and the fame 12 is not disposed.

In the example shown in FIG. 8A, the adhesive 14 is not disposed in the second region N. In the examples shown in FIG. 8B and FIG. 8C, the adhesive 14 is disposed in the second region N. No adhesive 14 is disposed in the third region P of the second region N which is located between the area near the inner edge of the lower face 12B of the frame 12 and the area directly under the one or plural second wiring layers 12M2.

In the example shown in FIG. 8B and FIG. 12B, at least a portion of the second portion 12N22 of the frame 12 overlaps the third region P of the base 11 in a top view, but the adhesive 14 is not disposed there. The adhesive 14, however, can reach the third region P as a result of being extended by the bonding process to partially reach the area above the second portion 12N22.

In a top view, 70% or more of the second wiring layer 12M2 or each second wiring layer 12M2 overlap the upper face 11A of the base 11. In a top view, 80% or more of the second wiring layer 12M2 or each second wiring layer 12M2 overlap the upper face 11A of the base 11. In a top view, 90% or more of the second wiring layer 12M2 or each second wiring layer 12M2 overlap the upper face 11A of the base 11. The larger the region where the upper face 11A and the second wiring layers 12M2 overlap, the more expansive the upper face 11A of the base 11 becomes, thereby achieving a package 10 with a good heat dissipation property.

The adhesive 14 is, for example, an adhesive containing AuSn. The adhesive 14 is, for example, an adhesive having a melting temperature of 300 °C or lower in a bonding process. If the temperature in the bonding process is too high, a poor adhesion could result between the graphite and the metal layer 11G in the base 11 in the bonding process. Thus, an adhesive having a melting temperature that is not high is preferably employed.

A lid 13 has an upper face 13A, a lower face 13B, and one or plural lateral faces 13C. The lid 13 is a cuboid having a flat sheet shape. The lid 13 does not have to be a cuboid.

The lid 13 has light transmissivity to allow light to pass through. Here, light transmissivity means a light transmittance of 80% or higher for the light that is incident on the lid 13. The lid 13 may have a non-transmissive region (region not having light transmissivity) in part.

The lid 13 is bonded to the frame 12. The lower face 13B of the lid 13 is bonded to the upper face 12A of the frame 12. The lid 13 is bonded to the first bonding layer 12N1 of the frame 12. The lid 13 does not overlap the second wiring layer 12M2 in a top view.

The lid 13 can be formed by using glass as a primary material, for example. Not limited to glass, the lid 13 may be formed by using, for example, sapphire as a primary material.

### Light Emitting Element 20

A light emitting element 20 has an upper face 21A, a lower face 21B, and plural lateral faces 21C. The shape of the upper face 21A is quadrangular. This quadrangular shape has long sides and short sides. In a top view, the outline of the light emitting element 20 is quadrangular. This quadrangular shape has long sides and short sides. The shape of the upper face 21A and the top view outline of the light emitting element 20 are not limited to this.

A light emitting element 20 has a light emission face 22 through which light is output. For example, one of the lateral faces 21C can be a light emission face 22. The lateral face 21C which serves as the light emission face 22 meets a short side of the upper face 21A. Moreover, for example, the upper face 21A can be a light emission face 22. The light emitting element 20 has one or plural light emission faces 22.

For a light emitting element 20, for example, a blue light emitting element can be employed. For example, for a light emitting element 20, a green light emitting element can be employed. For example, for a light emitting element 20, a red light emitting element can be employed. For a light emitting element 20, one that emits light of another color or wavelength may be employed.

Here, blue light refers to light whose peak wavelength falls within a 420 nm to 494 nm range. Green light refers to light whose peak wavelength falls within a 495 nm to 570 nm range. Red light refers to light whose peak wavelength falls within a 605 nm to 750 nm range.

Examples of light emitting elements 20 that emit blue or green light include light emitting elements that include nitride semiconductors. For the nitride semiconductors, for example, GaN-based semiconductors, such as GaN, InGaN, AlGaN, or the like can be employed. Examples of light emitting elements 20 that emit red light include those that include InAlGaP-based semiconductors, GaInP-based semiconductors, or GaAs-based semiconductors, such as GaAs, AlGaAs, or the like.

For a light emitting element 20, for example, a semiconductor laser element can be employed. For a light emitting element 20, a single emitter semiconductor laser element constructed with a single emitter can be employed.

For a light emitting element 20, a multi-emitter semiconductor laser element constructed with multiple emitters can be employed. Not limited to a semiconductor laser element, a light emitting diode or the like may be employed for the light emitting element 20.

Here, as one example of light emitting element 20, a semiconductor laser element will be described.

A semiconductor laser element emits laser light which has directivity. Divergent light that spreads is emitted from the light emission face 22 of a semiconductor laser element. The light emitted from a semiconductor laser element forms an elliptical far field pattern (hereinafter referred to as “FFP”) in a plane parallel to the light emission face 22. An FFP represents the shape and the light intensity distribution of the emitted light at a position that is distant from the light emission face of a semiconductor laser element.

The light passing the center of the elliptical FFP, in other words, the light having the peak intensity in the light intensity distribution of the FFP will be referred to as the light advancing or travelling along the optical axis. The light having an intensity of at least 1/e² relative to the peak intensity value in the light intensity distribution of an FFP will be referred to as the “main portion” of the light.

The shape of an FFP of the light emitted from a semiconductor laser element in a plane parallel to the light emission face 22 is elliptical which is longer in the stacking direction than the direction perpendicular to the stacking direction. The stacking direction refers to the direction in which semiconductor layers including an active layer are stacked in the semiconductor laser element. The direction perpendicular to the stacking direction in other words is the planar direction of the semiconductor layers.

The major axis direction of the elliptical shape of an FFP can also be referred to as the fast axis direction of the semiconductor laser element and the minor axis direction the slow axis direction of the semiconductor laser element.

Based on the light intensity distribution of an FFP, the divergence angle of the light having the 1/e² intensity of the peak intensity is referred to as the beam divergence angle of the light from the semiconductor laser element. Here, the divergence angle is represented by the angle formed by the light having the peak intensity (light along the optical axis) and the light having the 1/e² intensity of the peak intensity. The beam divergence angle can be obtained, for example, from the light intensity having one half of the peak intensity besides the 1/e² intensity of the peak intensity. In the present specification, when it is simply called the “beam divergence angle,” it refers to the beam divergence angle formed by the light having the 1/e² intensity of the peak intensity.

The fast axis direction divergence angle of the light emitted from a semiconductor laser element can be 20° or larger and smaller than 80°. The slow axis direction divergence angle of the light emitted from the semiconductor laser element can be larger than 0° and 20° at most. The fast axis direction divergence angle of the light is larger than the slow axis direction divergence angle.

For example, the fast axis direction divergence angle of blue light from a semiconductor laser element can be 30° or larger and smaller than 60°, and the slow axis direction divergence angle can be 5° or larger and smaller than 20°. For example, the fast axis direction divergence angle of green light from a semiconductor laser element can be 30° or larger and smaller than 60°, and the slow axis direction divergence angle can be 5° or larger and smaller than 20°. For example, the fast axis direction divergence angle of red light from a semiconductor laser element can be 40° or larger and smaller than 80°, and the slow axis direction divergence angle can be 5° or larger and smaller than 20°.

### Submount 30

Submount 30 has an upper face 31A, a lower face 31B, and one or plural lateral faces 31C. The upper face 31A can be considered as a mounting face on which other constituent elements are mounted. The shape of the upper face 31A is quadrangular. This quadrangular shape of the upper face 31A can have short sides and long sides. The shape of the upper face 31A does not have to be quadrangular.

The outline of the submount 30 in a top view is quadrangular. This quadrangular shape of the outline of the submount 30 can have short sides and long sides. The outline of the submount 30 in a top view does not have to be quadrangular. The submount 30, in a top view, can have an outline in which the length in one direction (hereinafter referred to as the short-length direction) is smaller than the length in the direction perpendicular thereto (hereinafter referred to as the long-length direction). In the submount 30 illustrated, the short-length direction coincides with the X direction and the long-length direction coincides with the Y direction.

A submount 30 can include a substrate 32A and an upper metal member 32B. The submount 30 can further include a lower metal member 32C. The upper metal member 32B is disposed on the upper face side of the substrate 32A. The lower metal member 32B is disposed on the lower face side of the substrate 32A. The submount 30 further has a wiring layer 33. The wiring layer 33 is disposed on the upper metal member 32B.

The substrate 32A has insulation properties. The substrate 32A is formed, for example, with silicon nitride, aluminum nitride, or silicon carbide. A ceramic which dissipates heat relatively well (has high thermal conductivity) can suitably be selected as a primary material for the substrate 32A.

For the primary material for the upper metal member 32B, a metal, such as copper, aluminum, or the like is used. The upper metal member 32B has one or plural metal layers. The upper metal member 32B can have plural metal layers formed of different metals as their primary materials.

For the primary material for the lower metal member 32C, a metal, such as copper, aluminum, or the like is used. The lower metal member 32C has one or plural metal layers. The lower metal member 32C can have plural metal layers formed of different metals as their primary materials.

The wiring layer 33 can be formed by using a metal. For example, the wiring layer 33 can be formed by using AuSn solder (AuSn metal layer).

For example, the short side direction or the short-length direction length of the submount 30 is 300 μm to 2000 μm. The long side direction or the long-length direction length of the submount 30 is 500 μm to 10000 μm.

The difference between the length in the long-length direction and the length in the short-length direction is 200 um to 9000 μm.

For example, the thickness of the submount 30 (the width in the direction perpendicular to the upper face 31A) is 100 μm to 500 μm. For example, the thickness of the substrate 32A is 100 μm to 400 μm. For example, the thickness of the upper metal member 32B is 0 μm to 200 μm.

For example, the thickness of the lower metal member 32C is 0 μm to 200 μm. For example, the thickness of the wiring layer 33 is 0.1 μm to 5 μm.

### Reflecting Member 40

A reflecting member 40 has a lower face 41A and a light reflecting face 41B that reflects light. The light reflecting face 41B is oblique to the lower face 41A. The straight line connecting the lower end and the upper end of the light reflecting face 41B is oblique to the lower face 41A. The oblique angle formed by the light reflecting face 41B and the lower face 41A will be referred to as the oblique angle of the light reflecting face 41B.

The light reflecting face 41B is a flat face. The light reflecting face 41B may be a curved face. The oblique angle of the light reflecting face 41B is 45 degrees. The oblique angle of the light reflecting face 41B does not have to be 45 degrees.

For the primary material for the reflecting member 40, glass, metal, or the like can be used. A heat resistant material can be suitably used as the primary material for the reflecting member 40. For the primary material, for example, glass such as quartz or BK7 (borosilicate glass), metals such as Al or the like can be used. The reflecting member 40 can be formed by using Si as a primary material.

Employing a reflecting material such as Al as the primary material allows the primary material to serve as the light reflecting face 41B. Instead of forming the light reflecting face 41B with the primary material, the reflecting member 40 may be generally shaped with a primary material, and a light reflecting face 41B formed on the surface thereof. In this case, the light reflecting face 41B can be formed by using a metal layer, such as Ag, Al, or the like, or a dielectric multilayer film, such as Ta₂O₅/SiO₂, TiO₂/SiO₂, Nb₂O₅/SiO₂, or the like.

The light reflecting face 41B has a reflectance of 90% or higher for the peak wavelength of the light irradiated on the light reflecting face 41B. The reflectance may be 95% or higher. The reflectance can be set to 99% or higher. The reflectance is 100% or lower, or lower than 100%.

### Protective Element 50

A protective element 50 has an upper face 51A, a lower face 51B, and one or plural lateral faces 51C. The shape of the protective element 50 is a cuboid. The protective element 50 does not have to be a cuboid.

The protective element 50 is provided for preventing a specific element (e. g., light emitting element 20) from being destroyed by excess current. One example of protective element 50 is a Zener diode. For the Zener diode, one formed with Si can be employed.

### Wire 60

A wire 60 is a linear conductive material having bonding parts at both ends. The bonding parts at both ends are used to achieve connections with other constituent elements. A wire 60 is, for example, a metal wire. For example, gold, aluminum, silver, copper, or the like can be used for the metal.

### Optical Member 70

An optical member 70 has an upper face 71A, a lower face 71B, and one or plural lateral faces 71C. The optical member 70 applies an optical action to the light that becomes incident on the optical member 70. The optical actions applied to the light by the optical member 70 include condensing, collimation, dispersion, polarization, diffraction, multiplexing, optical guiding, reflection, wavelength conversion, and the like.

An optical member 70 has an optical action face that applies an optical action. The upper face 71A, the lower face 71B, or a lateral face 71C can be an optical action face. The optical action face may be located at a position other than the upper face 71A, the lower face 71B, and the lateral faces 71C. For example, an optical action face may be formed inside of the optical member 70, rather than on the surface.

An optical member 70 can have one or plural lens faces 71D. A lens face 71D is an optical action face of the optical member 70. An optical member 70 having a lens face 71D may be called a lens member. The light that passes through the lens face 71D and exits the optical member 70 is subjected to an optical action by the optical member 70, such as condensing, dispersion, or collimation. For example, the optical member 70 is a collimating lens which changes the light that became incident on the optical member 70 to collimated light to be output.

The lens face 71D or each lens face 71D is disposed on the upper face 71A side. The lens face 71D may be disposed on the lower face 71B side. The upper face 71A and the lower face 71B are flat faces. The lens face 71D or each lens face 71D meets the upper face 71A. In a top view, the lens face 71D or each lens face 71D is enclosed by the upper face 71A.

In a top view, the outline of the optical member 70 is quadrangular. The top view outline of the optical member 70 does not have to be quadrangular. The lower face 71B is a flat face. No lens face 71D is formed on the lower face 71B side of the optical member 70. The shape of the lower face 71B is quadrangular. The shape of the lower face 71B does not have to be quadrangular.

In the optical member 70, the portion that overlaps a lens face 71D in a top view is referred to as a lens part 72A. In the optical member 70, the portion that overlaps the upper face 71A in a top view is referred to as the non-lens part 72B. The lower face 71B has a region that constitutes the lower face of the lens part 72A or each lens part 72A and a region that constitutes the lower face of the non-lens part 72B.

An optical member 70 can have plural lens faces 71D that are continuously formed in one direction. In a top view, the direction in which the lens faces 71D are arranged will be referred to as the coupling direction. In the optical member 70 illustrated, the coupling direction coincides with the X direction.

The lens faces 71D are formed such that the vertices of the lens faces 71d are positioned on a straight line. The imaginary line connecting the vertices is parallel to the lower face 71B of the optical member 70. The parallel here includes an error of up to ±5 degrees.

Two or more lens faces 71D, which are some or all of the lens faces 71D, can have the same curvature. All of the lens faces 71D can have the same curvature.

An optical member 70 has light transmissivity. The optical member 70 has a transmittance of 80% or higher for the peak wavelength of the light that becomes incident on the optical member 70. The optical member 70 may have a light transmissive region and a region that is not light transmissive (hereinafter referred to as a non-transmissive region). In the non-transmissive region, the transmittance for the peak wavelength of the light incident on the optical member 70 is 50% or lower. The optical member 70 can be formed, for example, by using glass such as BK7.

A light emitting device 1 will be described next.

In a light emitting device 1, one or plural light emitting elements 20 are arranged on the upper face 11A of the base 11. The one or plural light emitting elements 20 are enclosed in the through hole of the frame 12 in a top view. The one or plural light emitting elements 20 are positioned lower than the upper face 12A of the frame 12.

The light emitting element 20 or each light emitting element 20 emits light in a predetermined direction. The light emitting element 20 or each light emitting element 20 emits light from the light emission face 22 such that the light traveling along the optical axis is parallel to the upper face 11A. The predetermined direction in which the light is emitted from the light emission face 22 will be referred to as the fifth direction below. In the light emitting device 1 illustrated, the fifth direction is the positive Y direction.

A light emitting device 1 may include plural light emitting elements 20. In other words, the light emitting device 1 may be in the form of including a first light emitting element 20 or the form of including one or plural second light emitting elements 20 in addition to the first light emitting element 20.

In a light emitting device 1, plural light emitting elements 20 are arranged in one direction. The light emitting elements 20 are arranged in the direction perpendicular to the fifth direction in a top view. In the light emitting device 1 illustrated, the light emitting elements 20 are arranged in the X direction.

In the light emitting device 1, the plural light emitting elements 20 are composed of three or more light emitting elements 20. In this case, the light plural emitting elements 20 arranged in one direction includes a light emitting element 20 disposed between the light emitting elements 20 located at both ends.

The base 11 is placed such that the high thermal conduction direction of the graphite member 11F of the graphite stack 11E that is the closest layer to the upper face 11A of the base 11 is perpendicular to the light emission faces 22. Placing the base 11 in this manner makes it difficult for the heat generated by a light emitting element 20 to transfer to an adjacent light emitting element 20 in the layer of the graphite member 11F positioned closest to the upper face 11A, thereby achieving well-balanced heat dissipation for each light emitting element 20.

When comparing the light emitting elements 20 positioned at both ends to a light emitting element 20 positioned between both ends, each of the light emitting elements 20 positioned at both ends does not have adjacent light emitting elements 20 on one side, while a light emitting element 20 positioned between both ends has adjacent light emitting elements on both sides. If the high thermal conduction direction coincides with the fifth direction, the light emitting element 20 positioned between both ends more readily accumulates heat and thus more readily deteriorates than the light emitting elements 20 positioned at both ends. Thus, dissipating heat while focusing on the overall balance can contribute to extending the service life of the light emitting device 1. In the light emitting device 1 illustrated, the first graphite member 11F1 of the graphite stack 11E serves as the closest layer to the upper face 11A of the base 11.

In the graphite stack 11E, the number of graphite members 11F having the high thermal conduction direction that is perpendicular to the light emission face 22 is greater than the number of graphite members 11F having the high thermal conduction direction that is parallel to the light emission face 22 in planes parallel to the upper face 11A. The graphite stack 11E constructed in this manner can facilitate the thermal conduction more in the direction perpendicular to the light emission face 22 than the thermal conduction in the direction parallel to the light emission face 22.

In a light emitting device 1, light emitting elements 20 are arranged such that the inner lateral face 12C meeting the narrow-width portion 12A1 or the wide-width portion 12A2 of the frame 12 faces the light emission faces 22 of the light emitting elements 20. Accordingly, the second region N of the base 11 extends from the first region M in the direction perpendicular to the light emission faces 22. Facilitating the thermal conduction in the direction perpendicular to the light emission faces 22 and extending the second region N in the direction perpendicular to the light emission faces 22 can improve the heat dissipation effect of the base 11.

In the light emitting device 1 shown in the drawings, the inner lateral face 12C meeting the narrow-width portion 12A1 faces the light emission faces 22 of the light emitting elements 20. Accordingly, the wide-width portion 12A2 is distanced in the opposite direction to the fifth direction. The second wiring layer 12M2 is disposed on the upper face 12A at a position that is distant in the opposite direction to the fifth direction. The second region N extends from the first region M in the opposite direction to the fifth direction.

In a light emitting device 1, a light emitting element 20 or each light emitting element 20 is disposed on a submount 30. A light emitting element 20 is disposed on the wiring layer 33 of a submount 30. Plural light emitting elements 20 are not disposed on one submount 30. Plural light emitting elements 20 may be disposed on one submount 30.

A submount 30 is disposed on the upper face 11A of the base 11. The submount 30 is bonded to the upper face 11A of the base 11. The lower metal member 32C of the submount 30 is bonded to the upper face 11A of the base 11 via an adhesive. The thickness of the base 11 (width in the up/down direction) is larger than the thickness of the submount 30. This allows the base 11 to adjust the thicknesses of the graphite member 11F and the metal layer 11G more easily in forming the structure that includes the graphite stack 11E and the metal layer 11G, thereby increasing the design flexibility. A submount 30 is occasionally provided to adjust the height of the light emitted from a light emitting element 20, and in this case, the design flexibility with respect to thickness is limited.

The primary material for the lower metal member 32C of a submount 30 and the primary material for one or plural metal layers 11G of the base 11 are preferably the same material. This can reduce stress induced strain and crack formation risks when bonded to another constituent element, thereby improving the bonding reliability of the submount 30. For example, the primary material for the one or plural metal layers 11G is the primary material for the second metal layer 11G2. For example, the primary material for the lower metal member 32C and the second metal layer 11G2 is Cu.

The light emitting element 20 or each light emitting element 20 has a larger width in the fifth direction than in the direction perpendicular to the fifth direction in a top view. In a light emitting device 1, the light emitting elements 20 are arranged in the direction parallel to the long sides of the frame 12. Arranging the light emitting elements 20 in the direction that is parallel to the long sides of the frame 12 allows for the arrangement of a larger number of light emitting elements 20 than in the direction that is parallel to the short sides. This can increase the light output of the light emitting device 1.

In a light emitting device 1, the base 11 has a smaller width in the fifth direction than a width in the direction perpendicular to the fifth direction in a plane parallel to the upper face 11A. In the light emitting device 1 illustrated, the upper face 11A of the base 11 has a larger width in the X direction than a width in the Y direction.

The distance from the light emitting element 20 disposed at one end to the outer edge of the upper face 11A of the base 11 in the direction perpendicular to the fifth direction is smaller than the distance from the lateral face of the light emitting element that opposes the light emission face 22 to the outer edge of the upper face 11A of the base 11 in the fifth direction. The distance from the light emitting element disposed at one end to the outer edge of the upper face 11A of the base 11 in the direction perpendicular to the fifth direction is smaller than the distance from the light emission face 22 of the light emitting element 20 to the outer edge of the upper face 11A of the base 11 in the fifth direction. In other words, more width is secured for dissipating the heat generated by the light emitting element 20 in the fifth direction than in the direction perpendicular to the fifth direction.

In a light emitting device 1, one or plural reflecting members 40 are disposed on the upper face 11A of the base 11. A reflecting member 40 is disposed per light emitting element 20. The number of light emitting elements 20 is equal to the number of reflecting members 40 in a light emitting device 1. A reflecting member 40 may be disposed for plural light emitting elements 20.

The reflecting member 40 or each reflecting member 40 reflects the light emitted from the corresponding light emitting element 20. The light reflected by the light reflecting face 41B advances upwards. The light advancing along the optical axis travels from the light emission face 22 of the light emitting element 20 in the direction parallel to the upper face 11A, and then is reflected by the light reflecting face 41B to advance in the direction perpendicular to the upper face 11A.

A reflecting member 40 is disposed on the base 11 at a position distant from a light emitting element 20 in the fifth direction. The reflecting member 40 or each reflecting member 40 is positioned distant from the corresponding light emitting element 20 in the fifth direction. A region for disposing a reflecting member 40 is secured in the upper face 11A of the base 11 at a position distant from a light emitting element 20 in the fifth direction. Thus, extending the second region N from the light emitting element 20 in the opposite direction to the fifth direction can dissipate the heat generated by the light emitting element 20 in not only the fifth direction, but also the opposite direction to the fifth direction, thereby reducing the accumulation of heat in the vicinity of the light emitting element 20. Disposing a wide-width portion 12A2 of the frame 12 according to such an extension of the base 11, and utilizing the wide-width portion 12A2 as the region for providing the second wiring layer 12M2 can achieve an efficient package structure.

The light emitting elements 20 and the reflecting members 40 arranged on the upper face 11A of the base 11 are enclosed by the through hole of the frame 12 in a top view. The submounts 30 on which the light emitting elements 20 are disposed are similarly enclosed by the through hole of the frame 12 in a top view.

In a light emitting device 1, a protective element 50 is disposed on the upper face 31A of a submount 30. The protective element 50 may be disposed on the upper face 12F of a stepped portion 12E of the frame 12 in place of the upper face 31A of the submount 30. For example, a protective element 50 is disposed on the first wiring layer 12M1. A protective element 50 protects one or plural light emitting elements 20.

In a light emitting device, one or plural light emitting elements 20 are electrically connected to the wiring layer 12M of the frame 12. One or plural light emitting elements 20 are electrically connected to the wiring layer 12M through wires 60. The wires 60 include those that are bonded to the first wiring layer 12M1. The wires 60 include those that are bonded to the first wiring layer 12M1 disposed on the upper face 12F of the first stepped portion 12E1, and those that are bonded to the first wiring layer 12M1 disposed on the upper face 12F of the second stepped portion 12E2.

In a light emitting device 1, one or plural light emitting elements 20 are arranged in the internal space of the package 10. The light reflected by the reflecting members 40 exits the package 10 through the lid 13.

In a light emitting device 1, an optical member 70 is disposed on the package 10. The optical member 70 is bonded to the lid 13. The optical member 70 is fixed to the package 10. The light exiting the package 10 passes through the optical member 70. The light emitted from one or plural light emitting elements 20 passes through one or plural lens faces 71D of the optical member 70.

### Second Embodiment

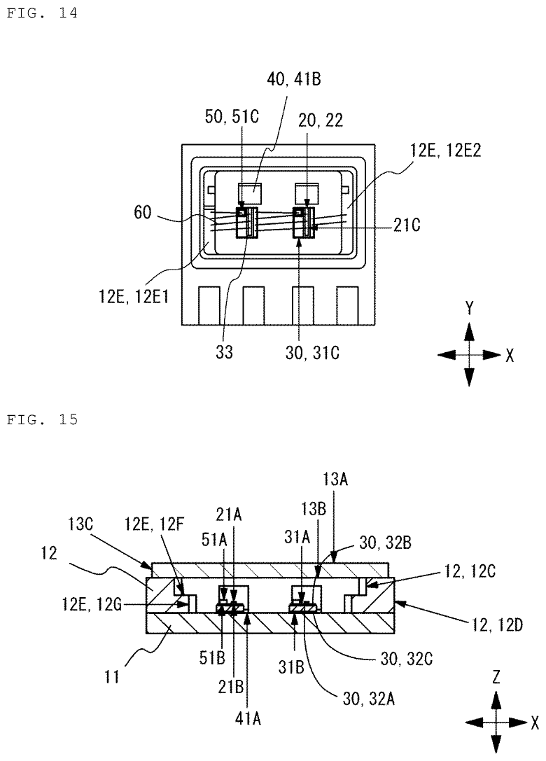

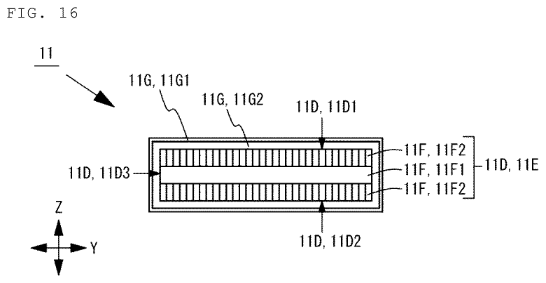

A light emitting device 2 according to a second embodiment will be explained. FIG. 2, FIG. 4B, FIG. 6, and FIGS. 8A to 16 are drawings explaining an exemplary form of the light emitting device 2. FIG. 13 is a perspective view of the light emitting device 2. FIG. 14 is a top view showing the constituent elements arranged in the internal space of the package 10 in the light emitting device 2. FIG. 15 is a cross-sectional view taken along line XV-XV in FIG. 2. FIG. 16 is a cross-sectional view of a base 11 in the light emitting device 2.

A light emitting device 2 includes plural constituent elements. The constituent elements include a package 10, plural light emitting elements 20, plural submounts 30, plural reflecting members 40, one or plural protective elements 50, plural wires 60, and an optical member 70.

The description of the light emitting device 1 and the constituent elements according to the first embodiment provided above except for the content considered inconsistent with FIGS. 2, 4B, 6, and 8 to 16 can also apply to the light emitting device 2. The description that is consistent will not be repeated here to avoid redundancy.

### Light Emitting Device 2

In a light emitting device 2, plural light emitting elements 20 are composed of a first light emitting element 20 and a second light emitting element 20. In other words, in the light emitting device 2, two light emitting elements 20 are mounted. The first light emitting element 20 and the second light emitting element 20 are arranged in the direction perpendicular to the fifth direction in a top view.

In the layout in which two light emitting elements 20 are placed side by side, each light emitting element 20 can be considered as being disposed at an end. There is no light emitting element 20 that has adjacent light emitting elements 20 on both sides. Accordingly, even if the heat from a light emitting element 20 transfers to the adjacent light emitting element 20, the heat dissipation balance of each light emitting element 20 would not be lost. In such a case, dissipating heat in the direction parallel to the light emission faces 22 can occasionally be more efficient than dissipating heat in the direction perpendicular to the light emission faces 22. This can apply to the case in which the light emitting elements 20 are shaped to be longer in the direction perpendicular to the light emission face 22 than in the direction parallel to the light emission face 22. Even if the heat moves in the direction perpendicular to the emission face 22, the heat can still remain directly under the light emitting element 20 until the heat moves the distance corresponding to the length of the light emitting element 20.

In a light emitting device 2, the base 11 is placed such that the graphite member 11F of the graphite stack 11E that is closest to the upper face 11A of the base 11 has the high thermal conduction direction in a plane parallel to the light emission face 22. Placing the base 11 in this manner allows the heat generated at the light emission face 22 and its vicinity of a light emitting element 20 to easily move out of the light emitting element 20, thereby producing a light emitting device 1 with a good heat dissipation property. In the light emitting device 2 shown in the drawings, the second graphite member 11F2 of the graphite stack 11E serves as the closest layer to the upper face 11A of the base 11.

The high thermal conduction direction of the graphite member 11F that is the closest layer to the upper face 11A of the base 11 is perpendicular to the direction in which the third portion 12P3 of the via wires 12P is elongated. This can facilitate the lateral dissipation of the heat generated at the third portion 12P3 relative to the direction in which the third portion 12P3 is elongated.

For a light emitting device 2, the form having two light emitting elements 20 has been described, but the point is that any situation would work if it does not require consideration for balanced heat dissipation for each light emitting element 20. For example, even if the plural light emitting elements 20 include three or more light emitting elements 20 which are arranged in one direction, the heat dissipation balance would not be lost greatly if the light emitting elements 20 are adequately spaced apart. For example, if the device includes only one light emitting element 20, there is no need to consider the heat dissipation balance in the absence of other light emitting elements 20. As such, a light emitting device 2 does not necessarily have to be limited to one that includes two light emitting elements 20, and can be any form that includes one or plural light emitting elements 20.

In the foregoing, certain embodiments of the present invention have been explained. Light emitting devices according to the present invention, however, are not strictly limited to those described in the embodiments. In other words, the present invention is implementable without limiting the outer shape or the structure of a light emitting device to any of those disclosed by the embodiments. Furthermore, it is not essential for the applicability of the present invention to include all of the constituent elements. For example, in the event that a certain constituent element of a light emitting device disclosed by any of the embodiments is not disclosed in the claim scope, we claim the applicability of the invention disclosed in the claim scope by recognizing the design flexibility for a person of ordinary skill in the art for such a constituent element through the use of an alternative, an omission, a shape change, a change in the materials employed, or the like.

Through the description in the present specification, the technical particulars listed below are disclosed.

### Aspect 1

A light emitting device comprising: a base using graphite as a primary material and having a first upper face; a submount disposed on the first upper face of the base; a first light emitting element disposed on the submount and configured to emit light in a first direction; a reflecting member disposed on the first upper face of the base at a position distant from the first light emitting element in the first direction; and a frame defining a through hole that surrounds the first light emitting element and the reflecting member in a top view, the frame having a second upper face, a lower face bonded to the base, the frame including one or plurality of wiring layers disposed on the second upper face at a position distant from the first light emitting element in the opposite direction to the first direction, wherein the first upper face of the base has a first region that covers the through hole in a top view and a second region disposed on the second upper face and extending from the first region to the area directly under the one or plurality of wiring layers

### Aspect 2)

The light emitting device according to aspect 1 wherein the base includes, a main part using graphite as a primary material, and a first metal layer disposed on an upper face of the main part and constituting the first upper face.

### Aspect 3

The light emitting device according to aspect 2 wherein the base includes a second metal layer disposed on the upper face of the main part, the first metal layer is disposed above the second metal layer, and the second metal layer is larger in thickness than the first metal layer.

### Aspect 4

The light emitting device according to aspect 3 wherein the second metal layer is disposed to cover all faces of the main part.

### Aspect 5

The light emitting device according to aspect 3 or 4 wherein the first metal layer is a metal layer containing Ni or Au, and the second metal layer is a metal layer containing Cu.

### Aspect 6

The light emitting device according to any one of aspects 1 to 5 wherein the base is bonded to the frame via an adhesive disposed near inner edges of the lower face of the frame that defines the through hole, and the adhesive is not disposed directly under at least a portion of the wiring layer.

### Aspect 7

The light emitting device according to any one of aspects 1 to 5 wherein the base is bonded at the lower face of the frame via an adhesive disposed near inner edges of the lower face of the frame that defines the through hole, and bonded at an area directly under the one or plurality of wiring layers disposed on the second upper face.

### Aspect 8

The light emitting device according to aspect 6 or 7 wherein the adhesive contains AuSn.

### Aspect 9)

The light emitting device according to any one of aspects 1 to 8 wherein the base includes a graphite stack formed by stacking, a first graphite member having higher thermal conductivity in the first direction than a second direction perpendicular to the first direction in a plane that is parallel to the first upper face, and a second graphite members having higher thermal conductivity in the second direction than the first direction, and the first graphite member of the graphite stack serves as a closest layer to the first upper face.

### Aspect 10

The light emitting device according to aspect 9 further comprising one or plurality of second light emitting elements disposed on the first upper face of the base and configured to emit light in the first direction, wherein the base has a smaller width in the first direction than a width in the second direction, the first light emitting element and the one or plurality of second light emitting elements are arranged in the second direction, and each of the first light emitting element and the one or plurality of second light emitting elements has a larger width in the first direction than a width in the second direction.

### Aspect 11

The light emitting device according to any one of aspects 1 to 8 wherein the base includes a graphite stack formed by stacking, a first graphite member having higher thermal conductivity in the first direction than a second direction perpendicular to the first direction in a plane that is parallel to the first upper face, and a second graphite members having higher thermal conductivity in the second direction than the first direction, and the second graphite member of the graphite stack serves as a closest layer to the first upper face.

### Aspect 12)

The light emitting device according to aspect 11 further comprising a second light emitting element disposed on the first upper face of the base and configured to emit light in the first direction, wherein the base has a smaller width in the first direction than a width in the second direction, the first light emitting element and the second light emitting element are arranged in the second direction, and each of the first light emitting element and the second light emitting element has a larger width in the first direction than a width in the second direction.

### Aspect 13)

The light emitting device according to any one of aspects 1 to 12 wherein the frame includes an additional wiring layer electrically connected, via a via wire provided internally, to one of the one or plurality of wiring layers disposed on the second upper face, the via wire includes a first portion connected to the additional wiring layer and extending in the up/down direction, a second portion connected to the one of the one or plurality of wiring layers disposed on the second upper face and extending in the up/down direction, and a third portion extending in a direction parallel to the second upper face, and a distance from the lower face of the frame to the third portion of the via wire in an up/down direction is smaller than a distance from the additional wiring layer to the third portion in the up/down direction.

The light emitting device disclosed in any of the embodiments can be used in projectors, automotive headlights, head-mounted displays, lighting fixtures, displays, and the like.

### REFERENCE NUMERALS

1, 2: light emitting device; 10: package; 11: base; 11A: upper face; 11B: lower face; 11C: lateral face; 11D: main part; 11D1: upper face; 11D2: lower face; 11D3: lateral face; 11E: graphite stack; 11F: graphite member; 11F1: first graphite member; 11F2: second graphite member; 11G: metal layer; 11G1: first metal layer; 11G2: second metal layer; 12: frame; 12A: upper face; 12A1: narrow-width portion; 12A2: wide-width portion; 12B: lower face; 12B1: narrow-width portion; 12B2: wide-width portion; 12B21: expanded portion; 12C: inner lateral face; 12D: outer lateral face; 12E: stepped portion; 12E1: first stepped portion; 12E2: second stepped portion; 12F: upper face; 12G: lateral face; 12M: wiring layer; 12M1: first wiring layer; 12M2: second wiring layer; 12N: bonding layer; 12N1: first bonding layer; 12N2: second bonding layer; 12N21: first portion; 12N22: second portion; 12N23: third portion; 12P: via wire; 12P1: first portion; 12P2: second portion; 12P3: third portion; 13: lid; 13A: upper face; 13B: lower face; 13C: lateral face; 14: adhesive; 20: light emitting element; 21A: upper face; 21B: lower face; 21C: lateral face; 22: light emission face; 30: submount; 31A: upper face; 31B: lower face; 31C: lateral face; 32A: substrate; 32B: upper metal member; 32C: lower metal member; 33: wiring layer; 40: reflecting member; 41A: lower face; 41B: light reflecting face; 50: protective element; 51A: upper face; 51B: lower face; 51C: lateral face; 60: wire; 70: optical member (lens member); 71A: upper face; 71B: lower face; 71C: lateral face; 71D: lens face (optical action face) ; 72A: lens part; and 72B: non-lens part.

What is claimed is:

1. A light-emitting device comprising:
a base using graphite as a primary material and having a first upper face;
a submount disposed on the first upper face of the base;
a first light emitting element disposed on the submount and configured to emit light in a first direction;
a reflecting member disposed on the first upper face of the base at a position distant from the first light emitting element in the first direction; and
a frame defining a through hole that surrounds the first light emitting element and the reflecting member in a top view, the frame having a second upper face, a lower face bonded to the base, the frame including one or plurality of wiring layers disposed on the second upper face at a position distant from the first light emitting element in the opposite direction to the first direction, wherein
the first upper face of the base has a first region that covers the through hole in a top view and a second region disposed on the second upper face and extending from the first region to the area directly under the one or plurality of wiring layers.

2. The light-emitting device according to claim 1, wherein the base includes,
a main part using graphite as a primary material, and
a first metal layer disposed on an upper face of the main part and constituting the first upper face.

3. The light-emitting device according to claim 2, wherein
the base includes a second metal layer disposed on the upper face of the main part,
the first metal layer is disposed above the second metal layer, and
the second metal layer is larger in thickness than the first metal layer.

4. The light-emitting device according to claim 3, wherein the second metal layer is disposed to cover all faces of the main part.

5. The light-emitting device according to claim 3, wherein
the first metal layer is a metal layer containing Ni or Au, and
the second metal layer is a metal layer containing Cu.

6. The light-emitting device according to claim 1, wherein
the base is bonded to the frame via an adhesive disposed near inner edges of the lower face of the frame that defines the through hole, and
the adhesive is not disposed directly under at least a portion of the wiring layer.

7. The light-emitting device according to claim 1, wherein the base is bonded at the lower face of the frame via an adhesive disposed near inner edges of the lower face of the frame that defines the through hole, and bonded at an area directly under the one or plurality of wiring layers disposed on the second upper face.

8. The light-emitting device according to claim 6, wherein the adhesive contains AuSn.

9. The light-emitting device according to claim 1, wherein
the base includes a graphite stack formed by stacking,
a first graphite member having higher thermal conductivity in the first direction than a second direction perpendicular to the first direction in a plane that is parallel to the first upper face, and
a second graphite members having higher thermal conductivity in the second direction than the first direction, and
the first graphite member of the graphite stack serves as a closest layer to the first upper face.

10. The light-emitting device according to claim 9, further comprising one or plurality of second light emitting elements disposed on the first upper face of the base and configured to emit light in the first direction, wherein
the base has a smaller width in the first direction than a width in the second direction,
the first light emitting element and the one or plurality of second light emitting elements are arranged in the second direction, and
each of the first light emitting element and the one or plurality of second light emitting elements has a larger width in the first direction than a width in the second direction.

11. The light-emitting device according to claim 1, wherein
the base includes a graphite stack formed by stacking,
a first graphite member having higher thermal conductivity in the first direction than a second direction perpendicular to the first direction in a plane that is parallel to the first upper face, and
a second graphite members having higher thermal conductivity in the second direction than the first direction, and
the second graphite member of the graphite stack serves as a closest layer to the first upper face.

12. The light-emitting device according to claim 11, further comprising a second light emitting element disposed on the first upper face of the base and configured to emit light in the first direction, wherein
the base has a smaller width in the first direction than a width in the second direction,
the first light emitting element and the second light emitting element are arranged in the second direction, and
each of the first light emitting element and the second light emitting element has a larger width in the first direction than a width in the second direction.

13. The light-emitting device according to claim 1, wherein
the frame includes an additional wiring layer electrically connected, via a via wire provided internally, to one of the one or plurality of wiring layers disposed on the second upper face,
the via wire includes a first portion connected to the additional wiring layer and extending in the up/down direction, a second portion connected to the one of the one or plurality of wiring layers disposed on the second upper face and extending in the up/down direction, and a third portion extending in a direction parallel to the second upper face, and
a distance from the lower face of the frame to the third portion of the via wire in an up/down direction is smaller than a distance from the additional wiring layer to the third portion in the up/down direction.
